(19) United States
(12) Patent Application Publication
(10) Pub. No.: US 2012/0257134 A1
(43) Pub. Date: Oct. 11, 2012

(54) TRANSFLECTIVE ARRAY SUBSTRATE AND TRANSFLECTIVE LIQUID DISPLAYER

(75) Inventors: Yang SUN, Beijing (CN); Kuanjun PENG, Beijing (CN); Yuting ZHANG, Beijing (CN)

(73) Assignee: BOE TECHNOLOGY GROUP CO., LTD., Beijing (CN)

(21) Appl. No.: 13/440,602

(22) Filed: Apr. 5, 2012

(30) Foreign Application Priority Data
Apr. 8, 2011 (CN) 201120102254.6

(51) Int. Cl. G02F 1/136; H01L 33/08

(52) U.S. Cl. 349/43; 257/59; 257/72; 257/E33.012

(57) ABSTRACT

The disclosed technology discloses a transflective array substrate and a transflective liquid crystal display. The array substrate comprises a plurality of pixel units, each of which comprises a reflective electrode and a transmissive electrode provided on a base substrate. An opaque gate line for shielding the light transmitted from the substrate to between reflective electrode and the transmissive electrode, the gate line is located between the reflective electrode and the transmissive electrode, and is located under the reflective electrode and the transmissive electrode; and a thin film transistor provided on the base substrate, a gate electrode of the thin film transistor is electrically connected to the gate line.

### BACKGROUND

Embodiments of the disclosed technology relate to a transflective array substrate and a transflective liquid crystal display (LCD).

A transflective thin film transistor liquid crystal display (TFT-LCD) adopts transmissive and reflective pixel structures, and possesses a backlight source and a reflection layer. Hence, this kind of TFT-LCD can not only employ the backlight source but also take advantage of an external light source (for example, sunshine) for display, and provide good view quality for a user in a strong light environment or a light-free environment.

According to different structures, the transflective liquid crystal displays can be divided into two categories: a double-cell-gap type and a single-cell-gap type. A double-cell-gap transflective TFT-LCD has different thicknesses of liquid crystal layer in a transmissive portion (transmission region) and a reflection portion (reflection region), and the thickness of the liquid crystal layer in the transmission region is twice of that in the reflection region commonly. In a single-cell-gap transflective liquid crystal display, the transmission region and the reflection region in the pixel unit have the same thickness of liquid crystal layer.

As for the double-cell-gap transflective liquid crystal display, the transmission region and the reflection region have different thicknesses of liquid crystal layer, thus the alignments of the liquid crystal molecules become irregular at the boundary between the two regions, and thus the display at the boundary become abnormal (for example, the display panel has light leakage) to make the characteristics such as contrast ratio, etc. degraded.

### SUMMARY

The embodiments of the disclosed technology provide a transflective array substrate and transflective liquid crystal display for improving display quality.

One embodiment of the disclosed technology provides a transflective array substrate, comprising a plurality of pixel units, each of which comprises: a reflective electrode and a transmissive electrode provided on a base substrate; an opaque gate line provided on the base substrate for shielding light transmitted from the substrate to between the reflective electrode and the transmissive electrode, the gate line being located between the reflective electrode and the transmissive electrode and under the reflective electrode and the transmissive electrode; and a thin film transistor provided on the base substrate, and a gate electrode of the thin film transistor being electrically connected the gate line.

Another embodiment of the disclosed technology provides a transflective liquid crystal display, comprising: a color filter substrate; an array substrate attached to the color filter substrate to form a liquid cell; a liquid crystal layer interposed between the color filter substrate and the array substrate; wherein the array substrate comprises a plurality of pixel units formed thereon, each of which comprises: a transmission region and a reflection region, wherein the liquid crystal layer in the transmission region has a different thickness from that in the reflection region; a reflective electrode and a transmissive electrode; an opaque gate line for shielding light transmitted from the array substrate to a boundary between the reflection region and the transmission region, wherein the gate line is located between the reflective electrode and the transmissive electrode and under the reflective electrode and the transmissive electrode; and a thin film transistor, a gate electrode of which is electrically connected with the gate line.

In the transflective pixel structure and the transflective liquid crystal display provided in the embodiments of the disclosed technology, the gate line passes through the pixel structure and divides one pixel unit into two regions, the upper half portion is a transmission region, and the lower half portion is a reflection region. The gate line shields the light from the base substrate to the boundary of the liquid crystal layer to reduce or eliminate abnormal light at the boundary, and thus the display quality is improved. Meanwhile, the embodiment of the disclosed technology modify the position of the gate line upwardly, without incorporating a new shielding layer, then this modification has substantially no influence on the pixel aperture ratio.

Further scope of applicability of the disclosed technology will become apparent from the detailed description given hereinafter. However, it should be understood that the detailed description and specific examples, while indicating preferred embodiments of the disclosed technology, are given by way of illustration only, since various changes and modifications within the spirit and scope of the disclosed technology will become apparent to those skilled in the art from the following detailed description.

### BRIEF DESCRIPTION OF THE DRAWINGS

The disclosed technology will become more fully understood from the detailed description given hereinafter and the accompanying drawings which are given by way of illustration only, and thus are not limitative of the disclosed technology and wherein:

FIG. 1 shows a structural schematic drawing of a double-cell-gap transflective liquid crystal display; and

FIG. 2 shows a structural schematic drawing of transflective pixel of an embodiment of this disclosed technology.

### DETAILED DESCRIPTION

Embodiment of the disclosed technology are made to overcome the defect of abnormal display generated at the boundary between two cell gaps in a conventional double-cell-gap transflective liquid crystal display, and achieves improvement of the display quality without reducing pixel aperture ratio.

Further detailed description is made to the embodiments of this disclosed technology with reference to the drawings.

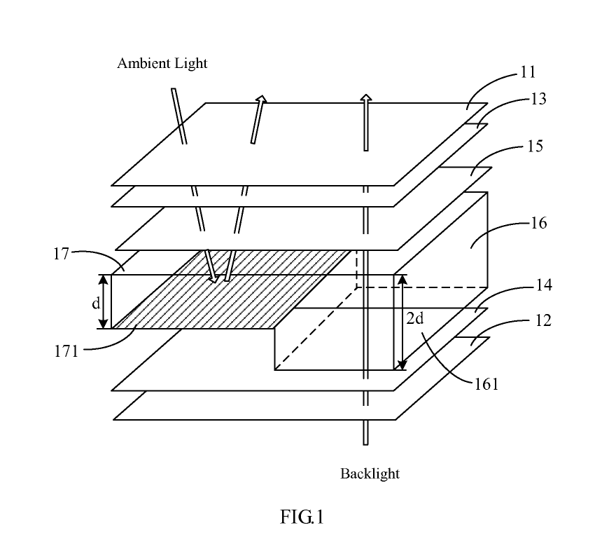

Firstly, FIG. 1 is a typical structural schematic drawing of a double-cell-gap transflective liquid crystal display. The liquid crystal layer 16, 17 is interposed between the color filter substrate 15 and the thin film transistor (TFT) array substrate 14. In each pixel unit defined by a gate line and a data line that are crossed with each other, the liquid crystal layer has a reflection region 17 in which a reflective electrode 171 for reflecting light is provided, and a transmission region 16 in which a transmissive electrode 161 for allowing light transmit is provided. The liquid crystal layer has different thicknesses in the reflection region 17 and the transmission region 16; for example, the liquid crystal layer in the transmission region 16 has a thickness twice than the thickness of the liquid crystal layer in the reflection region 17 so that the reflected ambient light (or environmental light) by the reflective electrode 171 of the reflection region 17 have the same phase difference as the light from the backlight and passing through the liquid crystal layer in the transmissive region 16. Besides, a λ/4 (quarter wave) sheet 13 and a polarizer sheet 11 are arranged sequentially on the color filter substrate 15, and a λ/4 sheet 14 and a polarizer sheet 12 are arranged sequentially on the TFT array substrate 14.

From FIG. 1, it can be seen that the double-cell-gap transflective liquid crystal display in a conventional technology, a step exists at the boundary of the liquid crystal layers of two different thicknesses, the alignment of the liquid crystal molecules adjacent to this boundary region becomes abnormal due to such influence, and thus the display effect is disadvantageously influenced to make the characteristics such as contrast ratio, etc. degraded.

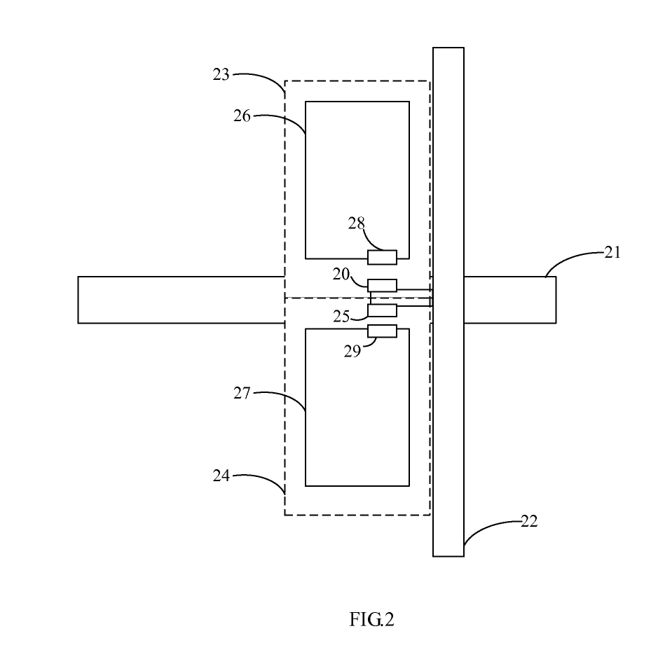

An embodiment of this disclosed technology makes modification on pixel structure of the transflective liquid crystal display. With reference to FIG. 2, the transflective array substrate provided by the embodiment comprises a plurality of the pixel units, which are defined by gate lines and data lines that are crossed with each other, each pixel unit comprises:

a gate line 21 which is opaque and provided on a base substrate (not shown);

a thin film transistor (not shown) provided on the gate line 21, the gate electrode of the thin film transistor and the gate line 21 being electrically connected; and

a reflective electrode 27 and a transmissive electrode 26 provided on the base substrate, the reflective electrode 27 and the transmissive electrode 26 being electrically insulated from each other.

The gate line 21 is provided between the reflective electrode 27 and the transmissive electrode 26, and under the reflective electrode 27 and the transmissive electrode 26 for shielding light to prevent the light from being emitted from the base substrate to between the reflective electrode 27 and the transmissive electrode 26.

In the embodiment, the gate line 21 can be formed by the opaque metal material, such as aluminum, molybdenum and the like. The base substrate may be a transparent substrate such as a glass substrate or a plastic substrate.

With above pixel structure, the back light generated by a backlight source under the base substrate passes through the substrate and reaches the gate line 21, and is blocked by the gate line 21, such that the light can not be incident to between the reflective electrode 27 and the transmissive electrode 26, and further can not be incident to the liquid crystal layer at the boundary between the reflection region 24 and the transmission region 23. Therefore the liquid crystal layer at the boundary essentially does not participate in display, and the abnormal display at the boundary can be reduced or eliminated, and thus the display quality is improved.

In an embodiment, each pixel unit can comprise two TFTs, which respectively control the applied voltages of the transmission region 24 and the reflection region 23. In this embodiment, the drain electrode 29 of one TFT is electrically connected with the reflective electrode 27, the source electrode 25 of this TFT is electrically connected with the data line 22 provided on the base substrate; the drain electrode 28 of the other TFT is electrically connected with the transmissive electrode 26, and the source electrode 20 of this TFT is electrically connected with the data line 22. The above two TFTs can have the substantially same size and function.

In another embodiment, each pixel unit can simultaneously control the applied voltages of the transmission region and the reflection region through same one thin film transistor. In this embodiment, the source electrode of the thin film transistor is electrically connected with the date line 22 on the base substrate, and the drain electrode of the thin film transistor is electrically connected with the transmission region 26 and the reflective electrode 27 respectively.

In the conventional transflective pixel structure, a gate line passes through one side of the pixel region; however, in this embodiment, the gate line passes through within the pixel structure and divides the pixel region into two regions, of which an upper half portion is a transmission region, and a lower half portion is a reflection region in the drawing. The two regions on the gate line can each have a thin film transistor of the same size, which respectively controls the applied voltage of each region. The metal layer of the gate line is opaque to block the light transmitted from the substrate to prevent it from being incident to the boundary of the liquid crystal layers of different thickness to reduce or eliminate abnormal light here to enhance the display quality. Meanwhile, the gate line is moved upwardly, and no new shielding layer is incorporated in the pixel structure, and thus the aperture ratio of the pixel unit is not disadvantageously influenced.

Based on the above transflective pixel structure, another embodiment of the disclosed technology provides a transflective liquid crystal display, which comprises: a color filter substrate;

a TFT array substrate attached to the color filter substrate to form a liquid cell;

a liquid crystal layer interposed between the color filter substrate and the TFT array substrate; and

a plurality of pixel units formed on the TFT array substrate, each pixel unit comprising a transmission region and a reflection region, the liquid crystal layer in the transmission region and that of the reflection region having different thicknesses.

Each pixel unit comprises: a reflective electrode and a transmissive electrode provided on the TFT array substrate;

an opaque gate line for shielding light transmitted from the TFT array substrate to a boundary between the transmission region and the reflection region, the gate line located between the reflective electrode and the transmissive electrode and under the reflective electrode and the transmissive electrode; and

a thin film transistor, a gate electrode of which is electrically connected with the gate line.

In this embodiment, the thickness of the liquid crystal layer in the transmission region is twice of the thickness of the liquid crystal layer in the reflection region. It should be understood that the proportion relationship between the thickness of the liquid crystal layer in the transmission region and that of the liquid crystal layer in the reflection region may not be twice strictly.

The gate line is formed by an opaque metal material, such as aluminum, molybdenum, or the like.

In an embodiment, in the transflective liquid crystal display, each pixel unit comprises two thin film transistors; the drain electrode of one thin film transistor (TFT) is electrically connected with the reflective electrode, the source electrode of this TFT is electrically connected with the data line provided on the TFT array substrate; the drain electrode of the other thin film transistor is electrically connected with the transmissive electrode, and the source electrode of the other TFT is electrically connected with the data line.

In another embodiment, in the transflective liquid crystal display, each pixel unit comprises one thin film transistor only, the source electrode of which is electrically connected with the data line provided on the TFT array substrate, and the drain electrode is electrically connected with the transmissive electrode and the reflective electrode respectively.

From the above, it can be seen that, different from the conventional structure, the embodiments of the disclosed technology modify the position of the gate line in each pixel unit on the TFT array substrate of the transflective liquid crystal display, and form the gate line under the boundary between the reflection region and the transmission region; the gate line shields the light incident to the boundary from the TFT array substrate so as to reduce or eliminate light leakage at the boundary between the transmission region and the reflection region from the TFT array substrate, and thus the display quality of the liquid crystal can be improved.

The embodiments of the disclosed technology being thus described, it will be obvious that the same may be varied in many ways. Such variations are not to be regarded as a departure from the spirit and scope of the disclosed technology, and all such modifications as would be obvious to those skilled in the art are intended to be comprised within the scope of the following claims.

What is claimed is:

1. A transflective array substrate, comprising a plurality of pixel units, each of which comprises:
a reflective electrode and a transmissive electrode provided on a base substrate;
an opaque gate line provided on the base substrate for shielding light transmitted from the base substrate to between the reflective electrode and the transmissive electrode, the gate line being located between the reflective electrode and the transmissive electrode and under the reflective electrode and the transmissive electrode; and
a thin film transistor provided on the base substrate, and a gate electrode of the thin film transistor being electrically connected the gate line.

2. The transflective array substrate according to claim 1, wherein the gate line is an opaque metal gate line.

3. The transflective array substrate according to claim 1, wherein each pixel unit further comprises a data line, and a source electrode of the thin film transistor is electrically connected with the data line, and a drain electrode is electrically connected with the transmissive electrode and the reflective electrode respectively.

4. The transflective array substrate according to claim 2, wherein each pixel unit further comprises a data line, and a source electrode of the thin film transistor is electrically connected with the data line, and a drain electrode is electrically connected with the transmissive electrode and the reflective electrode respectively.

5. The transflective array substrate according to claim 1, wherein each pixel unit further comprises a data line,
two thin film transistors are provided in the pixel unit, a drain electrode of one thin film transistor is electrically connected with the reflective electrode, and a source electrode of the thin film transistor is electrically connected with the data line; a drain electrode of the other thin film transistor is electrically connected with the transmissive electrode, and a source electrode of the other thin film transistor is electrically connected with the data line.

6. The transflective array substrate according to claim 2, wherein each pixel unit further comprises a data line,
two thin film transistors are provided in the pixel unit, a drain electrode of one thin film transistor is electrically connected with the reflective electrode, and a source electrode of the thin film transistor is electrically connected with the data line; a drain electrode of the other thin film transistor is electrically connected with the transmissive electrode, and a source electrode of the other thin film transistor is electrically connected with the data line.

7. A transflective liquid displayer, comprising:
a color filter substrate;
an array substrate attached to the color filter substrate to form a liquid cell;
a liquid crystal layer interposed between the color filter substrate and the array substrate;
wherein the array substrate comprises a plurality of pixel units formed thereon, each of which comprises:
a transmission region and a reflection region, wherein the liquid crystal layer in the transmission region has a different thickness from that in the reflection region;
a reflective electrode and a transmissive electrode;
an opaque gate line for shielding light transmitted from the array substrate to a boundary between the reflection region and the transmission region, wherein the gate line is located between the reflective electrode and the transmissive electrode and under the reflective electrode and the transmissive electrode; and
a thin film transistor, a gate electrode of which is electrically connected with the gate line.

8. The transflective liquid crystal display according to claim 7, wherein the gate line is an opaque metal gate line.

9. The transflective liquid crystal display according to claim 7, wherein each pixel unit further comprises a data line,
two thin film transistors are provided in the pixel unit, a drain electrode of one thin film transistor is electrically connected with the reflective electrode, and a source electrode of the thin film transistor is electrically connected with the data line; a drain electrode of the other thin film transistor is electrically connected with the transmissive electrode, and a source electrode of the other thin film transistor is electrically connected with the data line.

10. The transflective liquid crystal display according to claim 8, wherein each pixel unit further comprises a data line,
two thin film transistors are provided in the pixel unit, a drain electrode of one thin film transistor is electrically connected with the reflective electrode, and a source electrode of the thin film transistor is electrically connected with the data line; a drain electrode of the other thin film transistor is electrically connected with the transmissive electrode, and a source electrode of the other thin film transistor is electrically connected with the data line.

11. The transflective liquid crystal display according to claim 7, wherein each pixel unit further comprises a data line,
a source electrode of the thin film transistor is electrically connected with the data line, and a drain electrode is electrically connected with the transmissive electrode and the reflective electrode respectively.

12. The transflective liquid crystal display according to claim 8, wherein each pixel unit further comprises a data line,
a source electrode of the thin film transistor is electrically connected with the data line, and a drain electrode is electrically connected with the transmissive electrode and the reflective electrode respectively.

13. The transflective liquid crystal display according to claim 7, wherein the liquid crystal layer in the transmission region has a thickness twice of that in the reflection region.

14. The transflective liquid crystal display according to claim 7, wherein the liquid crystal layer in the transmission region has a thickness twice of that in the reflection region.
